(19) United States
(12) Patent Application Publication
(10) Pub. No.: US 2016/0319424 A1
(43) Pub. Date: Nov. 3, 2016

(54) SUBSTRATE PROCESSING APPARATUS

(71) Applicant: HITACHI KOKUSAI ELECTRIC INC., Tokyo (JP)

(72) Inventor: Akira TAKAHASHI, Toyama-shi (JP)

(73) Assignee: HITACHI KOKUSAI ELECTRIC INC., Tokyo (JP)

(21) Appl. No.: 15/097,382

(22) Filed: Apr. 13, 2016

(30) Foreign Application Priority Data
Apr. 28, 2015 (JP) 2015-091585

(51) Int. Cl. C23C 16/44; C23C 16/455; H01L 21/677; C23C 16/458

(52) U.S. Cl. CPC C23C 16/4412; C23C 16/4583; C23C 16/4408; C23C 16/4409; C23C 16/45523; H01L 21/67739

(57) ABSTRACT

The present invention provides a technique capable of suppressing the formation of particles. The substrate processing apparatus may include: a processing container where a substrate is processed; a process gas supply unit configured to supply a process gas into the processing container; a substrate support installed in the processing container; a first exhaust unit connected to the processing container; a shaft supporting the substrate support; a shaft support configured to support the shaft; an opening disposed at a bottom portion of the processing container and penetrated by the shaft; a flexible bellows disposed between the opening and the shaft support, wherein an inner space of the bellows is in communication with that of the processing container; and a gas supply/exhaust unit configured to supply an inert gas into the inner space of the bellows while exhausting an inner atmosphere of the bellows.

### BACKGROUND OF THE INVENTION

1. Field of the Invention

This non-provisional U.S. patent application claims priority under 35 U.S.C. §119 of Japanese Patent Application No. 2015-091585, filed on Apr. 28, 2015, the entire contents of which are hereby incorporated by reference.

The present disclosure relates to a substrate processing apparatus.

2. Description of the Related Art

Recently, a semiconductor device such as a flash memory has been highly integrated. Thus, patterns have been significantly miniaturized.

Since the miniaturized patterns are considerably affected by particles, it is necessary to suppress the formation of particles.

### SUMMARY OF THE INVENTION

It is an object of the present invention to provide a technique capable of suppressing the formation of particles.

According to an embodiment of the present invention, a substrate processing apparatus may include: a processing container where a substrate is processed; a process gas supply unit configured to supply a process gas into the processing container; a substrate support installed in the processing container; a first exhaust unit connected to the processing container; a shaft supporting the substrate support; a shaft support configured to support the shaft; an opening disposed at a bottom portion of the processing container and penetrated by the shaft; a flexible bellows disposed between the opening and the shaft support, wherein an inner space of the bellows is in communication with that of the processing container; and a gas supply/exhaust unit configured to supply an inert gas into the inner space of the bellows while exhausting an inner atmosphere of the bellows.

### BRIEF DESCRIPTION OF THE DRAWINGS

FIG. 1 is a diagram illustrating a substrate processing apparatus 100 according to a first embodiment of the present invention.

FIG. 2 is a diagram illustrating a front end portion of a first dispersion mechanism according to the first embodiment of the present invention.

FIG. 3 is a diagram illustrating an example in which a substrate support is rotated using a magnetic fluid seal in the substrate processing apparatus according to the first embodiment of the present invention.

FIG. 4 is a flowchart illustrating a substrate processing process which is performed in the substrate processing apparatus of FIG. 1.

FIG. 5 is a flowchart illustrating a film forming process of FIG. 4.

FIG. 6 is a diagram for describing a substrate transfer position of the substrate support in the substrate processing apparatus according to the first embodiment.

### DETAILED DESCRIPTION OF THE PREFERRED EMBODIMENTS

Hereinafter, a first embodiment of the present invention will be described.

<Apparatus Configuration>

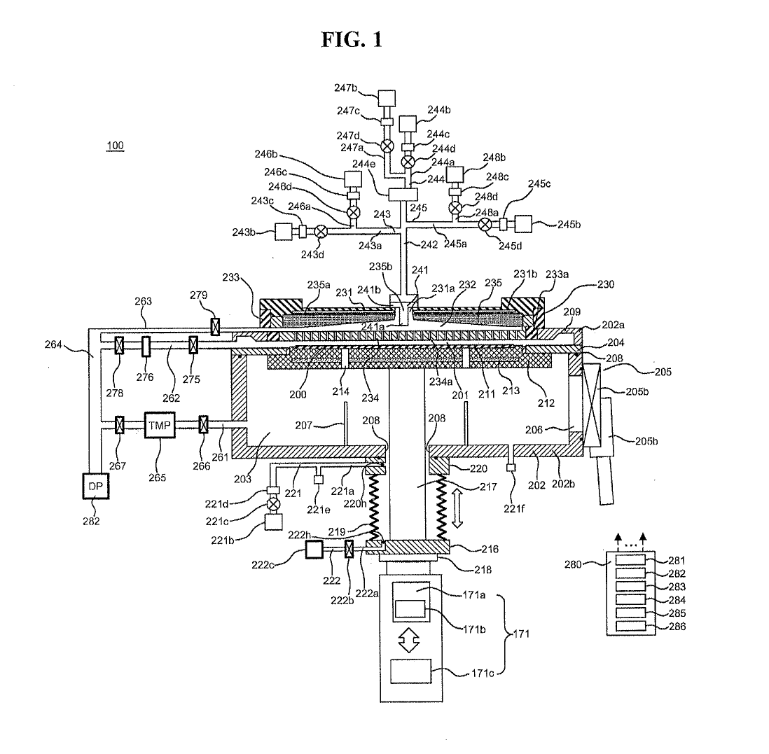

FIG. 1 is a diagram illustrating a substrate processing apparatus 100 according to a first embodiment of the present invention. As shown in FIG. 1, the substrate processing apparatus 100 is a sheet-type substrate processing apparatus.

(Processing Container)

As shown in FIG. 1, the substrate processing apparatus 100 includes a processing container 202. The processing container 202 is a flat airtight container having a circular transverse cross-section, for example. The processing container 202 is made of a metallic material such as aluminum (Al) and stainless steel (SUS). The processing container 202 includes a processing space 201 for processing a wafer 200 such as a silicon substrate and a transfer space 203 through which the wafer 200 is passed when being transferred to the processing space 201. The processing container 202 includes an upper container 202a and a lower container 202b. A partition plate 204 is installed between the upper container 202a and the lower container 202b.

A substrate loading/unloading port 206 disposed adjacent to a gate valve 205 is installed at a side surface of the lower container 202b. The wafer 200 is moved between a transfer chamber (not shown) and the transfer space 203 through the substrate loading/unloading port 206. Lift pins 207 are installed on the bottom portion of the lower container 202b. The lower container 202b is grounded.

The gate valve 205 includes a valve body 205a and a driving body 205b. The valve body 205a is fixed to a portion of the driving body 205b. When the gate valve is opened, the driving body 205b is moved away from the substrate loading/unloading port 206 of the processing container 202, and the valve body 205a is separated from the sidewall of the processing container 202. When the gate valve is closed, the driving body 205b is moved toward the substrate loading/unloading port 206 of the processing container 202, and the valve body 205a presses the sidewall of the processing container 202 so as to close the substrate loading/unloading port 206.

A substrate support 212 which supports the wafer 200 is installed in the processing space 201. The substrate support 212 includes a substrate support surface 211 on which the wafer 200 is placed and a heater 213 which is a heating source embedded in the substrate support 212. Through-holes 214 through which the lift pins 207 are passed are installed at positions corresponding to the lift pins 207 of the substrate support 212.

The substrate support 212 is supported by a shaft 217. FIG. 1 illustrates an example in which the upper end of the shaft 217 supports the substrate support 212. However, it is not necessary for the shaft 217 to support the substrate support 212 at the upper end thereof. For example, a hole may be formed at the bottom of the substrate support 212, and a support mechanism may be installed at a side surface of the shaft 217. When the above-described structure is employed, the shaft 217 is inserted into the hole, and the support mechanism installed at the side surface of the shaft 217 supports the substrate support.

The main portion of the shaft 217 has a slightly larger diameter than other portion of the shaft 217, and the shaft 217 is passed through an opening 208 formed at the bottom portion of the processing container 202, and connected to a lifting/lowering mechanism 218 outside the processing container 202 through a support plate 216. The lifting/lowering mechanism 218 lifts or lowers the shaft 217 and the support 212 such that the wafer 200 placed on the substrate support surface 211 can be lifted or lowered. The lower portion of the shaft 217 may be covered by a bellows 219. The inside of the processing container 202 is airtightly maintained. The support 212 is referred to as a shaft support. The shaft support may include the lifting/lowering mechanism 218. A lifting/lowering control unit 171 for controlling lifting/lowering of the shaft is installed in the lifting/lowering mechanism 218. The lifting/lowering control unit 171 is an elevator, for example. The lifting/lowering control unit 171 includes an operating unit 171a for lifting or lowering the lifting/lowering mechanism 218 which supports the shaft 217. The operating unit 171a includes a lifting/lowering mechanism 171b having a motor to perform a lifting/lowering operation, for example. An instruction unit 171c for instructing the operating unit 171a to rotate may be installed in the lifting/lowering control unit 171, the operating unit 171a constituting the lifting/lowering control unit 171. The instruction unit 171c is electrically connected to a controller 280. The instruction unit 171c controls the operating unit 171a based on an instruction of the controller 280.

The bellows 219 is made of stainless steel, for example. The bellows 219 is manufactured by connecting a plurality of annular stainless steel plates through welding. The bellows 219 has elasticity.

An upward pressed portion 220 is installed between the upper end of the bellows 219 and the bottom portion of the processing container 202. An inert gas supply pipe 221a constituting an inert gas supply unit 221 is connected to the upward pressed portion 220. Specifically, the upward pressed portion 220 is provided with an inert gas supply hole 220h. The inert gas supply pipe 221a is connected to the inert gas supply hole 220h. The inert gas supply pipe 221a communicates with the inner space of the bellows 219.

An inert gas supply source 221b, a valve 221c, a mass flow controller (MFC) 221d and a pressure detector 221e are sequentially installed in the inert gas supply pipe 221a from the upstream side to the downstream side of the inert gas supply pipe 221a. An inert gas supplied from the inert gas supply source 221b is supplied between the upper end of the bellows 219 and the bottom portion of the processing container 202 through the valve 221c and the MFC 221d. The inert gas supply unit 221 includes the valve 221c, the MFC 221d and the inert gas supply pipe 221a. The inert gas supply unit 221 may further include the inert gas supply source 221b and the pressure detector 221e. The inert gas supply unit 221 is referred to as a bellows side inert gas supply unit or first inert gas supply unit.

A bellows side exhaust pipe 222a included in a bellows side gas exhaust unit 222 (also referred to as “second exhaust unit”) is connected to the support plate 216, and communicates with the inner space of the bellows 219.

A valve 222b and a pump 222c are sequentially installed in the bellows side exhaust pipe 222a from the upstream side to the downstream side of the bellows side exhaust pipe 222a. As the valve 222b is opened and the pump 222c is driven, the atmosphere of the inner space of the bellows 219 may be exhausted. The bellows side gas exhaust unit 222 includes the valve 222b and the bellows side exhaust pipe 222a. The bellows side gas exhaust unit 222 may further include the pump 222c. The first inert gas supply unit 221 and the bellows side gas exhaust unit 222 are collectively referred to as a bellow-side gas supply/exhaust unit.

The inner space of the bellows 219 indicates a space defined by the bellows.

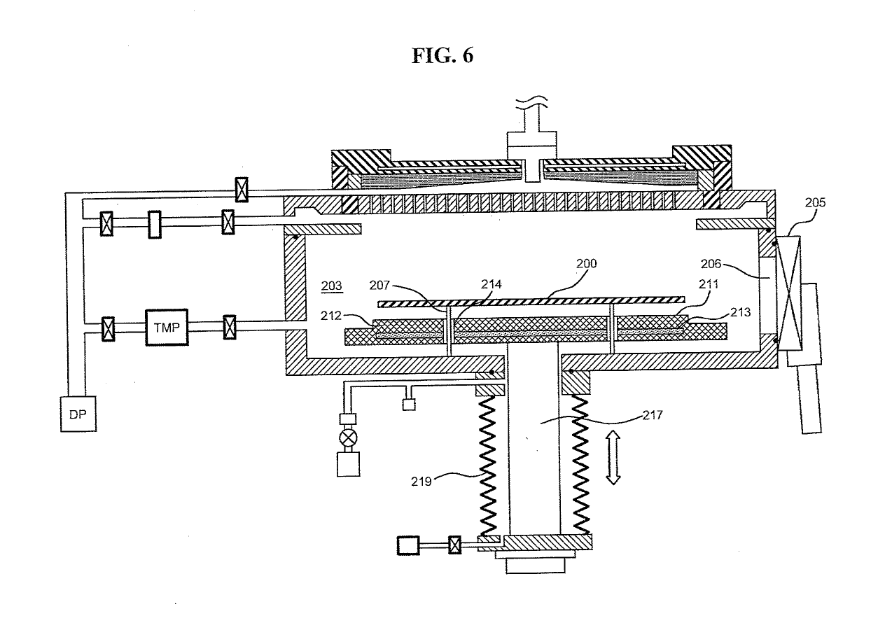

When the wafer 200 is transferred, the substrate support 212 is lowered until the substrate support surface 211 is at a position (transfer position) facing the substrate loading/unloading port 206 as shown in FIG. 6. When the wafer 200 is processed, the substrate support 212 is lifted until the wafer 200 is at a processing position within the processing space 201 as shown in FIG. 1.

Specifically, when the substrate support 212 is lowered to the transfer position, the upper end portions of the lift pins 207 protrude from the top surface of the substrate support surface 211, and the lift pins 207 support the wafer 200 from thereunder. Furthermore, when the substrate support 212 is lifted to the processing position, the lift pins 207 are buried below the top surface of the substrate support surface 211, and the substrate support surface 211 supports the wafer 200 from thereunder. Since the lift pins 207 come in direct contact with the wafer 200, the lift pins 207 may be made of quartz or alumina.

A pressure sensor 221f is installed on the processing container 202. The pressure sensor 221f detects the pressure of the processing container 202. The pressure sensor 221f is installed around the opening 208 at the bottom portion of the processing container 202, for example. As the pressure sensor 221f is installed around the opening 208 at the bottom of the processing container 202, the pressure sensor 221f detects the pressure around the opening 208 at the bottom portion of the processing container 202.

A shower head 230 serving as a gas dispersion mechanism is installed at the upper portion (upstream side) of the processing space 201. A gas introduction hole 231a through which a first dispersion mechanism 241 is passed is formed in a cover 231 of the shower head 230. The first dispersion mechanism 241 includes a front end portion 241a inserted into the shower head and a flange 241b fixed to the cover 231.

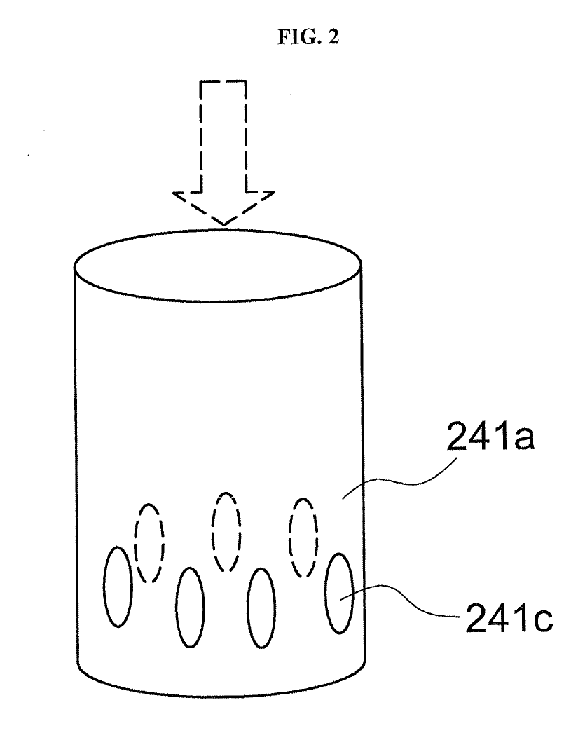

FIG. 2 is a diagram illustrating the front end portion 241a of the first dispersion mechanism 241. An arrow depicted by a dotted line in FIG. 2 indicates the direction where a gas is supplied. The front end portion 241a is formed in a pillar shape or cylindrical shape. Dispersion holes 241c are installed at the side surface of the cylinder. A gas supplied through a gas supply unit (gas supply system) described later is supplied to a buffer space 232 through the front end portion 241a and the dispersion holes 241c.

The cover 231 of the shower head includes a conductive metal, and is used as an electrode for generating plasma in the buffer space 232 and the processing space 201. An insulation block 233 is installed between the cover 231 and the upper container 202a, and insulates the cover 231 from the upper container 202a.

The shower head 230 is provided with a dispersion plate 234 which is a second dispersion mechanism for dispersing a gas. The upstream side of the dispersion plate 234 corresponds to the buffer space 232, and the downstream side of the dispersion plate 234 corresponds to the processing space 201. The dispersion plate 234 is provided with through-holes 234a. The dispersion plate 234 is disposed to face the substrate support surface 211.

A shower head heating unit 231b for heating the shower head 230 is installed in the cover 231. The shower head heating unit 231b heats the shower head 230 at a temperature at which a gas supplied to the buffer space 232 is not liquefied. The shower head heating unit 231b heats the shower head 230 at a temperature of approximately 100° C., for example.

The dispersion plate 234 may be formed in a disk shape. The through-holes 234a are disposed across the entire surface of the dispersion plate 234. The through-holes 234a may be arranged at even intervals, and the outermost through-holes 234a are arranged at the outer side than the outer circumference of the wafer placed on the substrate support 212.

A gas guide 235 is installed to guide the gas supplied through the first dispersion mechanism 241 to the dispersion plate 234. The gas guide 235 has an inner diameter that increases as the gas guide 235 is close to the dispersion plate 234. The inside of the gas guide 235 has a cone shape. The lower end of the gas guide 235 is disposed at the outer side than the through-holes 234a formed at the outermost circumference of the dispersion plate 234.

The upper container 202a includes the insulation block 233 and a flange 233a. The insulation block 233 is fixedly placed on the flange 233a. The dispersion plate 234 is fixedly placed on the flange 233a. The cover 231 is fixed to the top surface of the insulation block 233. According to the above-described structure, the cover 231, the dispersion plate 234 and the insulation block 233 may be sequentially removed from the top.

A film forming process described later includes a purge process for exhausting the atmosphere of the buffer space 232. During the film forming process, different gases are alternately supplied, and the purge process is performed to remove a residual gas between the processes of supplying different gases. The alternate supply process of alternately supplying different gases is repeated a plurality of times until a desired thickness is obtained. Thus, a large amount of time is required until a film is formed. Therefore, when the alternate supply process is performed, the process time needs to be shortened as much as possible. Furthermore, in order to improve the yield, the substrate is required to have a uniform film thickness or quality in the surface thereof.

Therefore, the substrate processing apparatus according to the present embodiment includes the dispersion plate which uniformly disperses a gas. The buffer space at the upstream side of the dispersion plate has a smaller volume than the processing space 201, for example, which makes it possible to shorten the time required for performing the purge process of exhausting the atmosphere of the buffer space.

(Gas Supply System)

The first dispersion mechanism 241 is connected to the gas introduction hole 231a formed in the cover 231 of the shower head 230. A common gas supply pipe 242 is connected to the first dispersion mechanism 241. The first dispersion mechanism 241 has a flange which is fixed to the cover 231 or the flange of the common gas supply pipe 242 through a screw or the like.

The first dispersion mechanism 241 and the common gas supply pipe 242 communicate with each other, and a gas supplied to the common gas supply pipe 242 is supplied into the shower head 230 through the first dispersion mechanism 241 and the gas introduction hole 231a.

A first gas supply pipe 243a, a second gas supply pipe 244a and a third gas supply pipe 245a are connected to the common gas supply pipe 242. The second gas supply pipe 244a is connected to the common gas supply pipe 242 through a remote plasma unit 244e.

A first element containing gas is supplied mainly through a first gas supply system 243 including the first gas supply pipe 243a, and a second element containing gas is supplied mainly through a second gas supply system 244 including the second gas supply pipe 244a. When a wafer is processed, an inert gas is supplied mainly through a third gas supply system 245 including the third gas supply pipe 245a. When the shower head 230 or the processing space 201 is cleaned, a cleaning gas is supplied mainly through the third gas supply system 245 including the third gas supply pipe 245a.

(First Gas Supply System)

A first gas supply source 243b, an MFC 243c serving as a flow rate controller and a valve 243d serving as an opening/closing valve are sequentially installed in the first gas supply pipe 243a from the upstream side to the downstream side of the first gas supply pipe 243a.

The first element containing gas is supplied to the shower head 230 through the MFC 243c and the valve 243d, which are installed in the first gas supply pipe 243a, and the common gas supply pipe 242.

The first element containing gas is one of source gases, that is, process gases. The first element may include titanium (Ti). That is, the first element containing gas may include a titanium containing gas. The first element containing gas may have a solid, liquid, or gaseous state at room temperature and pressure. When the first element containing gas has a liquid state at room temperature and pressure, a vaporizer (not shown) may be installed between the first gas supply source 243b and the MFC 243c. In the preset specification, a case in which the first element containing gas has a gaseous state will be taken as an example for description.

The downstream end of a first inert gas supply pipe 246a is connected to the downstream side of the valve 243d installed in the first gas supply pipe 243a. An inert gas supply source 246b, an MFC 246c serving as a flow rate controller and a valve 246d serving as an opening/closing valve are sequentially installed in the first inert gas supply pipe 246a from the upstream side to the downstream side of the first inert gas supply pipe 246a.

According to the present embodiment, the inert gas may include nitrogen (N₂) gas. In addition to the N₂ gas, rare gases such as helium (He) gas, neon (Ne) gas and argon (Ar) gas may be used as the inert gas.

The first element containing gas supply system 243 (also referred to as a Ti containing gas supply system) includes the first gas supply pipe 243a, the MFC 243c and the valve 243d.

A first inert gas supply system includes the first inert gas supply pipe 246a, the MFC 246c and the valve 246d. The first inert gas supply system may further include the inert gas supply source 234b and the first gas supply pipe 243a.

The first element containing gas supply system 243 may further include the first gas supply source 243b and the first inert gas supply system.

According to the present embodiment, the first gas supply system 243 is also referred to as a first gas supply unit or source gas supply unit.

(Second Gas Supply System)

The remote plasma unit 244e is installed at the downstream side of the second gas supply pipe 244a. A second gas supply source 244b, a MFC 244c serving as a flow rate controller and a valve 244d serving as an opening/closing valve are sequentially installed in the second gas supply pipe 244a from the upstream side to the downstream side of the second gas supply pipe 244a.

The second element containing gas is supplied into the shower head 230 through the MFC 244c and the valve 244d, which are installed in the second gas supply pipe 244a, the remote plasma unit 244e and the common gas supply pipe 242. The second element containing gas is excited to a plasma state by the remote plasma unit 244e, and irradiated onto the wafer 200.

The second element containing gas is one of process gases. The second element containing gas may be considered as a reactive gas or modification gas.

The second element containing gas contains a second element different from the first element. The second element includes any one of oxygen (O), nitrogen (N) and carbon (C), for example. According to the present embodiment, the second element containing gas is nitrogen containing gas, for example. Specifically, ammonia (NH₃) gas may be used as the nitrogen containing gas.

The second element containing gas supply system 244 (also referred to as a nitrogen containing gas supply system) includes the second gas supply pipe 244a, the MFC 244c and the valve 244d.

The downstream end of a second inert gas supply pipe 247a is connected to the downstream side of the valve 244d installed in the second gas supply pipe 244a. An inert gas supply source 247b, an MFC 247c serving as a flow rate controller and a valve 247d serving as an opening/closing valve are sequentially installed in the second inert gas supply pipe 247a from the upstream side to the downstream side of the second inert gas supply pipe 247a.

An inert gas is supplied into the shower head 230 through the MFC 247c and the valve 247d, which are installed in the second inert gas supply pipe 247a, the second gas supply pipe 244a and the remote plasma unit 244e. The inert gas serves as a carrier gas or dilution gas during a thin film forming process S104.

The second inert gas supply system includes the second inert gas supply pipe 247a, the MFC 247c and the valve 247d. The second inert gas supply system may further include the inert gas supply source 247b, the second gas supply pipe 244a and the remote plasma unit 244e.

The second element containing gas supply system 244 may further include the second gas supply source 244b, the remote plasma unit 244e and the second inert gas supply system.

According to the present embodiment, the second gas supply system 244 is also referred to as a second gas supply unit or reactive gas supply unit.

(Third Gas Supply System)

A third gas supply source 245b, an MFC 245c serving as a flow rate controller and a valve 245d serving as an opening/closing valve are sequentially installed in the third gas supply pipe 245a from the upstream side to the downstream side of the third gas supply pipe 245a.

An inert gas serving as a purge gas is supplied to the shower head 230 through the MFC 245c and the valve 245d, which are installed in the third gas supply pipe 245a, and the common gas supply pipe 242.

According to the present embodiment, the inert gas may include nitrogen (N₂) gas. In addition to the N₂ gas, rare gases such as helium (He) gas, neon (Ne) gas and argon (Ar) gas may be used as the inert gas.

The downstream end of a cleaning gas supply pipe 248a is connected to the downstream side of the valve 245d installed in the third gas supply pipe 245a. A cleaning gas supply source 248b, an MFC 248c serving as a flow rate controller and a valve 248d serving as an opening/closing valve are sequentially installed in the cleaning gas supply pipe 248a from the upstream side to the downstream side of the cleaning gas supply pipe 248a.

The third gas supply system 245 includes the third gas supply pipe 245a, the MFC 245c and the valve 245d.

The cleaning gas supply system includes the cleaning gas supply pipe 248a, the MFC 248c and the valve 248d. The cleaning gas supply system may further include the cleaning gas supply source 248b and the third gas supply pipe 245a.

The third gas supply system 245 may further include the third gas supply source 245b and the cleaning gas supply system.

During a substrate processing process, an inert gas is supplied into the shower head 230 through the MFC 245c and the valve 245d, which are installed in the third gas supply pipe 245a, and the common gas supply pipe 242. During a cleaning process, a cleaning gas is supplied into the shower head 230 through the MFC 248c and the valve 248d, which are installed in the cleaning gas supply pipe 248a, and the common gas supply pipe 242.

The inert gas supplied from the inert gas supply source 245b serves as a purge gas for purging a residual gas in the processing container 202 or the shower head 230 during the substrate processing process. During the cleaning process, the inert gas may serve as a carrier gas or dilution gas of the cleaning gas.

The cleaning gas supplied from the cleaning gas supply source 248b removes by-products adhering to the shower head 230 or the processing container 202 during the cleaning process.

According to the present embodiment, the cleaning gas may include nitrogen trifluoride (NF₃) gas, for example. As the cleaning gas, hydrogen fluoride (HF) gas, chlorine trifluoride (ClF₃) gas, fluorine (F₂) gas or a combination thereof may be used.

The third gas supply system 245 is also referred to as an inert gas supply unit or processing space side inert gas supply unit. The third gas supply system 245 is also referred to as a second inert gas supply unit so as to be distinguished from the first inert gas supply unit.

The first gas supply system 243, the second gas supply system 244 and the third gas supply system 245 are collectively referred to as a gas supply unit.

(Exhaust Unit)

An exhaust unit for exhausting the atmosphere of the processing container 202 includes a plurality of exhaust pipes connected to the processing container 202. Specifically, the exhaust unit includes an exhaust pipe 263 (first exhaust pipe) connected to the buffer space 232, an exhaust pipe 262 (second exhaust pipe) connected to the processing space 201 and an exhaust pipe 261 (third exhaust pipe) connected to the transfer space 203. An exhaust pipe 264 (fourth exhaust pipe) is connected to the downstream sides of the exhaust pipes 261, 262 and 263.

The exhaust pipe 261 is connected to the transfer space 203 through a sidewall or lower portion of the transfer space 203. A turbo molecular pump (TMP) 265 which is a vacuum pump for providing a high vacuum or ultra-high vacuum is installed in the exhaust pipe 261. A valve 266 which is a first exhaust valve for the transfer space is installed at the upstream side of the TMP 265 installed in the exhaust pipe 261. The exhaust pipe 261 and the TMP 265 are collectively referred to as a transfer space exhaust unit.

The exhaust pipe 262 is connected to the processing space 201 through a sidewall of the processing space 201. An automatic pressure controller (APC) 276 serving as a pressure controller for maintaining the internal pressure of the processing space 201 at a predetermined pressure is installed in the exhaust pipe 262. The APC 276 includes a valve body (not shown) capable of adjusting a degree of opening, and adjusts the conductance of the exhaust pipe 262 according to an instruction from the controller described later. A valve 275 is installed at the upstream side of the APC 276 installed in the exhaust pipe 262. The exhaust pipe 262, the valve 275 and the APC 276 are collectively referred to as a processing container side exhaust unit (also referred to as “first exhaust unit”).

The exhaust pipe 263 is connected to a portion different from the portion to which the exhaust pipe 262 is connected. The exhaust pipe 263 is connected the portion between the through-holes 234a and the lower end of the gas guide 235 in a vertical direction, for example. A valve 279 is installed in the exhaust pipe 263. The exhaust pipe 263 and the valve 279 are collectively referred to as a shower head exhaust unit.

A dry pump (DP) 282 is installed in the exhaust pipe 264. As shown in FIG. 1, the exhaust pipes 263, 262 and 261 are sequentially connected to the exhaust pipe 264 from the upstream side to the downstream side of the exhaust pipe 264, and the DP 282 is installed at the downstream side of the exhaust pipe 264. The DP 282 exhausts the atmospheres of the buffer space 232, the processing space 201 and the transfer space 203 through the exhaust pipes 263, 262 and 261, respectively. The DP 282 functions as a backing pump when the TMP 265 is operated. That is, the TMP 265 which is a high vacuum (or ultra-high vacuum) pump cannot independently exhaust the atmospheres to the atmospheric pressure. Thus, the DP 282 is used as a backing pump which exhausts the atmospheres to the atmospheric pressure. The valves of the above-described exhaust unit may include an air valve.

A valve 278 is installed between the exhaust pipe 264 and the APC 276 installed in the exhaust pipe 262. The valve 278 blocks the APC 276 from the exhaust pipe 264, such that a gas passing through the exhaust pipe 264 is not introduced into the APC 276. Thus, except a case in which an exhaust process through the exhaust pipe 264 is performed, the valve 278 is closed. The processing container side exhaust unit (first exhaust unit) may include the valve 278.

A valve 267 is installed between the TMP 265 of the exhaust pipe 261 and the exhaust pipe 264. The valve 267 blocks the TMP 265 from the exhaust pipe 264, such that a gas passing through the exhaust pipe 264 is not introduced into the TMP 265. Thus, except the case in which the exhaust process through the exhaust pipe 264 is performed, the valve 267 is closed. The transfer space exhaust unit may include the valve 267.

(Controller)

As shown in FIG. 1, the substrate processing apparatus 100 includes a controller 280 for controlling operations of the components of the substrate processing apparatus 100. The controller 280 includes at least an operation unit 281, a memory unit 282, a transmitting and receiving unit 284 and a comparison unit 285. The controller 280 is connected to the above-described components, calls a program, recipe or table from the memory unit 282 according to an instruction of an upper controller or user, and controls the operations of the above-described components according to the contents of the program, recipe or table. The table includes information obtained by comparing temperature information and control parameters. The controller 280 may be embodied by a dedicated computer or general computer. For example, an external memory device 283 storing the program (for example, a magnetic disk such as magnetic tape, flexible disk or hard disk, an optical disk such as CD or DVD, a magneto-optical disk such as MO or a semiconductor memory such as USB memory (USB flash drive) or memory card) may be prepared and used to install the program in a general computer, in order to embody the controller 280 according to the present embodiment. The unit for supplying the program to the computer is not limited to the external memory device 283. For example, a communication unit such as the Internet or a dedicated line may be used to supply the program without the external memory device 283 interposed therebetween. The memory unit 282 or the external memory device 283 may be embodied by a non-transitory computer-readable recording medium storing a program. Hereafter, the memory unit 282 and the external memory device 283 are collectively referred to as a recording medium. In the present specification, when the term ‘recording medium’ is used, it may indicate a case in which only the memory unit 282 is included, a case in which only the external memory device 283 is included or a case in which both of the memory unit 282 and the external memory device 283 are included. The transmitting and receiving unit 284 exchanges information with other components. For example, the transmitting and receiving unit 284 receives temperature information from a temperature monitor unit (not shown). The comparison unit 285 compares information such as a table, read from the memory unit 282, to information received from another component, and then extracts a parameter for control. The comparison unit 285 compares the information received from the temperature monitor unit (not shown) to the table stored in the memory unit, and extracts a parameter for operating a robot (not shown), for example.

<Substrate Processing Process>

Next, a process of forming a thin film on the wafer 200 using the substrate processing apparatus 100 will be described. In the following descriptions, the operations of the components constituting the substrate processing apparatus 100 are controlled by the controller 280.

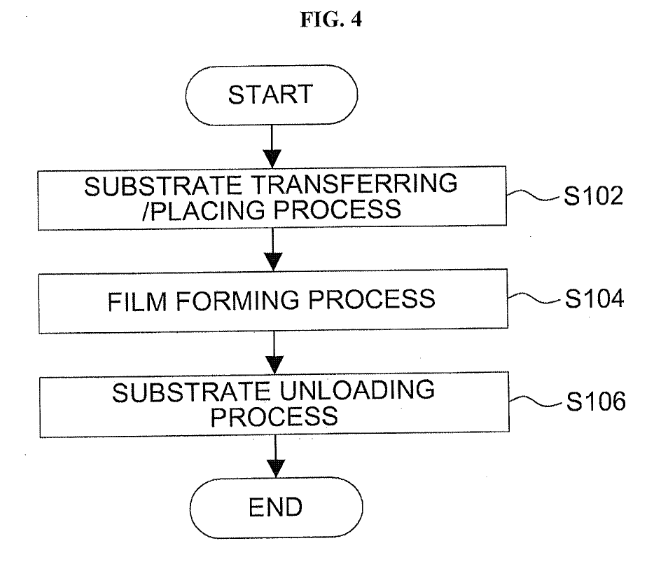

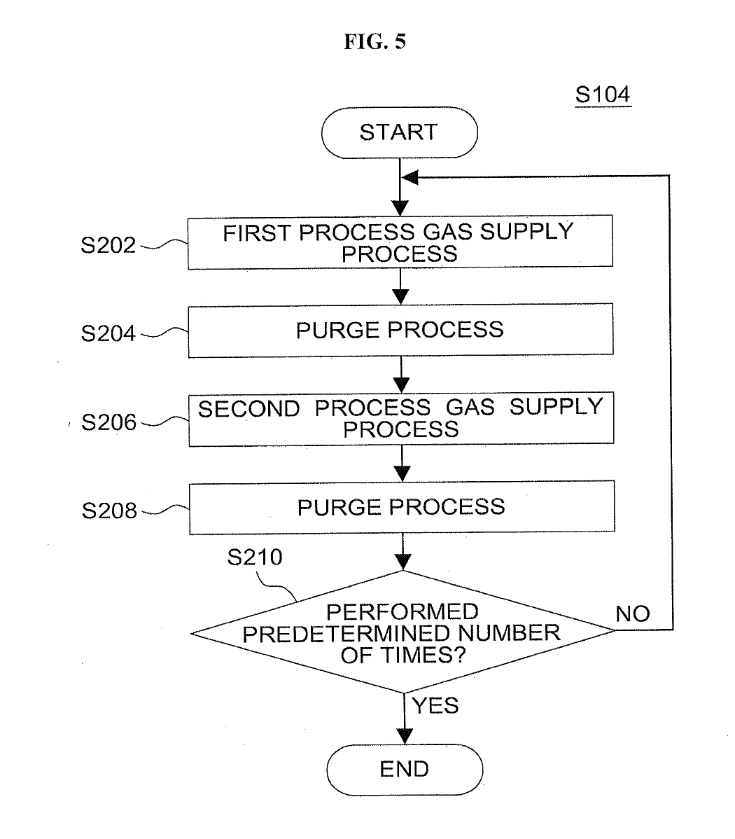

FIG. 4 is a flowchart illustrating a substrate processing process according to the first embodiment. FIG. 5 is a flowchart illustrating a film forming process of FIG. 4.

Hereafter, a process of forming a titanium nitride film on the wafer 200 using TiCl₄ gas and ammonia (NH₃) gas as a first process gas and a second process gas, respectively, will be taken as an example for description.

<Substrate Transferring/Placing Process (S102)>

As the substrate support 212 is lowered to the transfer position of the wafer 200 in the substrate processing apparatus 100 (refer to FIG. 6), the lift pins 207 are passed through the through-holes 214 of the substrate support 212. As a result, the lift pins 207 protrude only to a predetermined level from the surface of the substrate support 212. Subsequently, as the gate valve 205 is opened, the transfer space 203 communicates with a transfer chamber (not shown). The wafer 200 is transferred to the transfer space 203 from the transfer chamber through a wafer transferring mechanism, and placed on the lift pins 207. Thus, the wafer 200 is horizontally supported on the lift pins 207 protruding from the surface of the substrate support 212.

An inert gas is supplied toward the opening 208 and the shaft 217 from the inert gas supply pipe 221a. Simultaneously, the inner atmosphere of the bellows 219 is exhausted through the bellows side exhaust pipe 222a.

Whenever the substrate support 212 is moved in the vertical direction, the connection portions between the respective plates of the bellows 219 creak. Thus, when the substrate support 212 is repetitively moved in the vertical direction, the connection portions are deteriorated. The plates of the bellows are connected by welding, for example. Therefore, when the connection portions are deteriorated, fine metal pieces are formed in the inner space of the bellows 219. The formed metal pieces are lifted by the vertical movement of the shaft, and spread into the processing container 202.

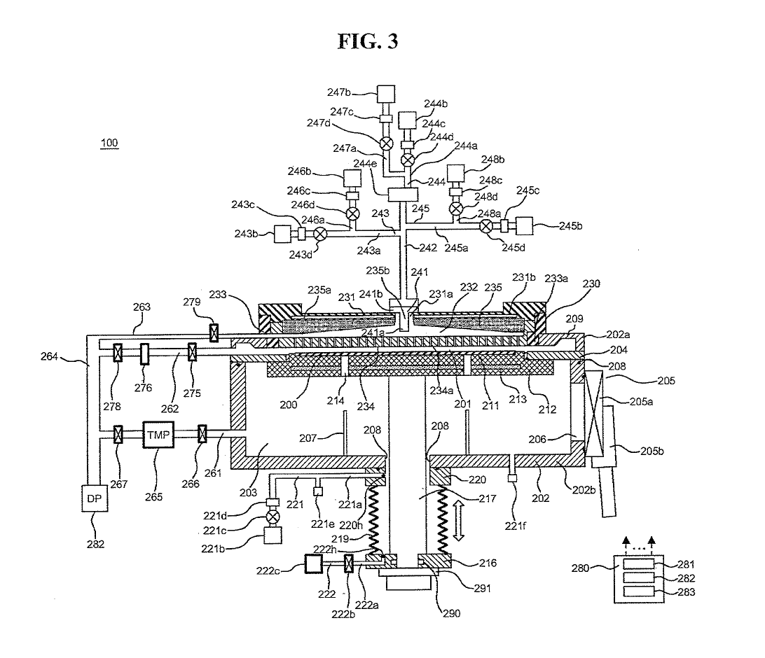

As shown in FIG. 3, the substrate processing apparatus includes a magnetic fluid seal 290 which rotatably supports the rotating shaft 291 for rotating the substrate support 212, while airtightly sealing the rotating shaft 291. In the substrate processing apparatus shown in FIG. 3, magnetic particles are separated from the magnetic fluid seal 290, as the magnetic fluid seal 290 is deteriorated with time or dried by a heat source therearound. Then, while the shaft 217 is moved in the vertical direction, the magnetic particles penetrate into the bellows 219 from the magnetic fluid seal 290.

When the gate valve 205 is opened, particles may penetrate into the bellows 219. That is because, when the gate valve 205 is opened, a film attached to the gap or contact surface between the substrate loading/unloading port 206 and the gate valve 205 may be peeled off. The film attached to the substrate loading/unloading port 206 and the gate valve 205 is formed by a first or second gas supply process S202 or S206 which is described later. A portion of the peeled film is discharged from the processing container by the TMP 265 or the like, and another portion of the peeled film collides with the shaft 217 so as to penetrate to the inner space of the bellows 219.

Although dusts such as metal pieces, particles and magnetic particles penetrate to the inner space of the bellows 219, it is difficult to exhaust the dusts using the TMP 265. Thus, when the pressure is varied during the film forming process, the dusts may be lifted into the processing container 202 from the bellows 219. As a result, the dusts may adhere to the substrate, thereby having a bad influence. Therefore, during the substrate loading/unloading process, it is desirable to prevent dusts from penetrating to the inner space of the bellows 219.

Thus, according to the present embodiment, an inert gas is supplied through the inert gas supply pipe 221a such that dusts cannot penetrate to the inner space of the bellows 219 during the substrate loading/unloading process.

The inner atmosphere of the bellows 219 is exhausted through the bellows side exhaust pipe 222a, such that foreign matters from the bellows 219 or the magnetic fluid seal 290 do not penetrate into the processing space 201. Thus, metal pieces do not penetrate into the processing container 202.

When the wafer 200 is loaded into the processing container 202, the wafer transferring mechanism is retreated to the outside of the processing container 202, and the gate valve 205 is closed to seal the processing container 202. Then, the substrate support 212 is lifted to place the wafer 200 on the substrate support surface 211 formed in the substrate support 212. Then, as the substrate support 212 is additionally lifted, the wafer 200 is lifted to the processing position within the above-described processing space 201.

When the wafer 200 is lifted to the processing position within the processing space 201 after the wafer 200 is loaded in the transfer space 203, the valves 266 and 267 are closed. The valve 266 blocks the transfer space 203 from the TMP 265 such that the transfer space 203 and the TMP 265 do not communicate with each other, and the valve 267 blocks the TMP 265 from the exhaust pipe 264 such that the TMP 265 and the exhaust pipe 264 do not communicate with each other. Then, the exhaust of the transfer space 203 by the TMP 265 is ended. As the valve 275 is opened, the processing space 201 and the APC 276 communicate with each other, and as the valve 278 is opened, the APC 276 and the DP 282 communicate with each other. The APC 276 adjusts the conductance of the exhaust pipe 262 so as to control the exhaust flow rate of the processing space 201 by the DP 282. Then, the processing space 201 is maintained at a predetermined pressure (for example, a high vacuum of 10⁻⁵ Pa to 10⁻¹ Pa).

Simultaneously, while the substrate support 212 is at the processing position, an inert gas is supplied between the shaft 217 and the inner wall of the opening 208 through the inert gas supply pipe 221a, and the inner atmosphere of the bellows 219 is exhausted through the bellows side exhaust pipe 222a. Thus, the gas staying around the lower portion of the shaft 217 is prevented from penetrating to the inner space of the bellows 219, and foreign matters from the bellows 219 or the magnetic fluid seal 290 are prevented from penetrating into the processing container. The controller 280 controls the bellows side inert gas supply unit and the bellows side gas exhaust unit (second exhaust unit) 222, such that the conductance of the space between the shaft 217 and the opening 208 is larger than the conductance of the bellows side exhaust pipe 222a.

While the inside of the processing container 202 is exhausted during the substrate transferring/placing process S102, N₂ gas may be supplied as an inert gas into the processing container 202 by the inert gas supply system. That is, as at least the valve 245d of the third gas supply system 245 is opened while the inside of the processing container 202 is exhausted by the TMP 265 or the DP 282, N₂ gas may be supplied into the processing container 202.

After the wafer 200 is placed on the substrate support 212, power is supplied to the heater 213 embedded in the substrate support 212. Then, the surface of the wafer 200 is controlled at a predetermined temperature. The temperature of the wafer 200 ranges from room temperature to 500° C., or desirably ranges from room temperature to 400° C. At this time, based on the temperature information detected by the temperature sensor (not shown), the conduction state of the heater 213 is controlled to adjust the temperature of the heater 213.

(Film Forming Process (S104))

Next, a film forming process S104 is performed. Hereafter, referring to FIG. 5, the film forming process S104 will be described in detail. The film forming process S104 includes an alternate supply process in which a process of alternately supplying different process gases is repeated.

(First Process Gas Supply Process (S202))

When the wafer 200 reaches a desired temperature through the operation of heating the wafer 200, the controller 280 opens the valve 243d and controls the MFC 243c to set the flow rate of TiCl₄ gas to a predetermined flow rate. The flow rate of supplied TiCl₄ gas may range from 100 sccm to 5,000 ccm, for example. Simultaneously, the valve 245d of the third gas supply system 245 is opened to supply N₂ gas through the third gas supply pipe 245a. At this time, N₂ gas may be supplied through the first inert gas supply system. Before the first process gas supply process S202, N₂ gas may also be supplied through the third gas supply pipe 245a.

An inert gas is supplied to the space between the shaft 217 and the inner wall of the opening 208 through the inert gas supply pipe 221a. While the inert gas is supplied, the inner atmosphere of the bellows 219 is exhausted through the bellows side exhaust pipe 222a. At this time, the amount of supplied inert gas is larger than that in a purge process S208 described later. When the amount of supplied inert gas is larger than that in the purge process S208 described later, it is possible to more reliably prevent the first element containing gas from penetrating into the inner space of the bellows 219.

More desirably, the supply of the inert gas is controlled, so that the pressure around the opening 208 within the processing container 202 becomes lower than the pressure of the space between the shaft 217 and the inner wall of the opening 208. As such, the supply of the inert gas can be controlled to more reliably prevent the atmosphere of the processing container 202 from penetrating to the inner space of the bellows 219.

The TiCl₄ gas supplied to the processing space 201 through the first dispersion mechanism 241 is supplied onto the wafer 200. As the TiCl₄ gas comes in contact with the surface of the wafer 200, a titanium containing layer is formed as a first element containing layer. The TiCl₄ gas supplied through the first dispersion mechanism 241 also stays in a gap 232b.

The titanium containing layer has a predetermined thickness and distribution according to the internal pressure of the processing container 202, the flow rate of TiCl₄ gas, the temperature of the substrate support 212, and the time during which TiCl₄ gas stays in the processing space 201. A predetermined layer may be formed on the wafer 200 in advance. A predetermined pattern may also be formed on the wafer 200 or the predetermined film in advance.

When a predetermined time has elapsed after the TiCl₄ gas was supplied, the valve 243d is closed to stop the supply of the TiCl₄ gas. During the process S202 As shown in FIG. 5, the valves 275 and 278 are opened, and the pressure of the processing space 201 is adjusted to a predetermined pressure by the APC 276. During the process S202, the valves of the exhaust unit other than the valves 275, 278 and 222b are all closed.

(Purge Process (S204))

Subsequently, N₂ gas is supplied through the third gas supply pipe 245a so as to purge the shower head 230 and the processing space 201. At this time, the valves 275 and 278 are opened, and the pressure of the processing space 201 is adjusted to a predetermined pressure by the APC 276. The valves of the exhaust unit other than the valves 275 and 278 are all closed. Thus, TiCl₄ gas which was not coupled to the wafer 200 during the first process gas supply process S202 is removed from the processing space 201 through the exhaust pipe 262 by the DP 282.

Then, N₂ gas is supplied through the third gas supply pipe 245a so as to purge the shower head 230. At this time, the valves 275 and 278 are closed, and the valve 279 is opened. The other values of the exhaust unit are closed. That is, when the shower head 230 is purged, the processing space 201 is blocked from the APC 276, and the APC 276 is blocked from the exhaust pipe 264. Thus, while the pressure control by the APC 276 is stopped, the buffer space 232 and the DP 282 communicate with each other. Then, the TiCl₄ gas remaining in the shower head 230 (buffer space 232) is exhausted from the shower head 230 through the exhaust pipe 262 by the DP 282.

Following the first process gas supply process S202, an inert gas is supplied to the space between the shaft 217 and the inner wall of the opening 208 through the inert gas supply pipe 221a. Simultaneously, the inner atmosphere of the bellows 219 is exhausted through the bellows side exhaust pipe 222a. At this time, the amount of supplied inert gas is adjusted to be smaller than that in the first gas supply process S202. As the amount of supplied inert gas is adjusted to be smaller than that in the first gas supply process S202, the gas can be efficiently used.

When the operation of purging the shower head 230 is ended, the valves 278 and 275 are opened to resume the pressure control through the APC 276, and the valve 279 is closed to block the shower head 230 from the exhaust pipe 264 such that the shower head 230 and the exhaust pipe 264 do not communicate with each other. The valves of the exhaust unit other than the valves 278 and 275 are closed. At this time, N₂ gas is continuously supplied through the third gas supply pipe 245a so as to purge the shower head 230 and the processing space 201. During the purge process S204, a purge operation through the exhaust pipe 263 is performed before and after a purge operation is performed through the exhaust pipe 262, but only a purge operation through the exhaust pipe 262 may be performed. Alternatively, the purge operation through the exhaust pipe 262 and the purge operation through the exhaust pipe 263 may be performed at the same time.

(Second Process Gas Supply Process (S206))

After the purge process S204, the valve 244d is opened to supply ammonia gas in a plasma state into the processing space 201 through the remote plasma unit 244e and the shower head 230.

At this time, the MFC 244c is controlled to set the flow rate of ammonia gas to a predetermined flow rate. The flow rate of supplied ammonia gas may range from 100 sccm to 5,000 ccm. N₂ gas serving as a carrier gas may be supplied with the ammonia gas through the second inert gas supply system. During the process S206, the valve 245d of the third gas supply system 245 is also opened to supply N₂ gas through the third gas supply pipe 245a.

The ammonia gas in a plasma state, supplied to the processing container 202 through the first dispersion mechanism 241, is supplied onto the wafer 200. As the titanium containing layer formed on the wafer 200 is modified by the ammonia gas in a plasma state, a layer containing titanium and nitrogen elements (modified layer) is formed on the wafer 200.

The modified layer has a predetermined thickness, a predetermined distribution, and a predetermined penetration depth of nitrogen atoms with respect to the titanium containing layer, according to the internal pressure of the processing container 202, the flow rate of nitrogen-containing gas, the temperature of the substrate support 212, and the power supply state of the remote plasma unit 244e.

After a predetermined time has elapsed, the valve 244d is closed to stop the supply of the nitrogen containing gas.

During the process S206, the valves 275 and 278 are opened, and the pressure of the processing space 201 is adjusted to a predetermined pressure by the APC 276, as in the above-described process S202. The valves of the exhaust unit other than the valves 275, 278 and 222b are all closed.

Following the purge process S204, an inert gas is supplied to the space between the shaft 217 and the inner wall of the opening 208 through the inert gas supply pipe 221a, while the inner atmosphere of the bellows 219 is exhausted through the bellows side exhaust pipe 222a. At this time, the amount of supplied inert gas is larger than that in the purge gas supply process S204. As the amount of supplied inert gas is larger than that in the purge gas supply process S204, the penetration of the second element containing gas can be more reliably prevented.

(Purge Process (S208))

Subsequently, the same purge process as the process S204 is performed. Since the operations of the components constituting the substrate processing apparatus 100 are performed in the same manner as the process S204, the detailed descriptions thereof are omitted herein.

(Determination (S210))

The controller 280 determines whether a cycle including the processes S202, S204, S206 and S208 was performed a predetermined number of times (n cycles).

When the cycle was not performed the predetermined number of times [No at the process S210], the cycle including the first process gas supply process S202, the purge process S204, the second process gas supply process S206, and the purge process S208 is repeated. When the cycle was performed the predetermined number of times [Yes at the process S210], the process shown in FIG. 5 is ended.

During the first process gas supply process S202, the first process gas may leak through the gap between the substrate support 212 and the partition plate 204, and penetrate into the substrate loading/unloading port 206 while being supplied to the transfer space 203. Similarly, during the second process gas supply process S206, the second process gas may also leak through the gap between the substrate support 212 and the partition plate 204, and penetrate into the substrate loading/unloading port 206 while being supplied to the transfer space 203. Since the processing space 201 and the transfer space 203 are partitioned by the substrate support 212 and the partition plate 204, it is difficult to exhaust the atmosphere of the transfer space 203 through the purge processes S204 and S206. Thus, the gases penetrating into the substrate loading/unloading port 206 may react with each other, such that a film is formed on the inner surface of the substrate loading/unloading port 206 or the surface of the valve body 205a, facing the transfer space 203. As described above, the film becomes dusts during the substrate transferring/placing process S102. Therefore, as described with reference to the substrate transferring/placing process S102, the inert gas is supplied to the space between the shaft 217 and the opening 208 through at least the inert gas supply pipe 221a during the substrate transferring/placing process S102.

Referring back to FIG. 4, a substrate unloading process S106 is performed.

(Substrate Unloading Process (S106))

During the substrate unloading process S106, the substrate support 212 is lowered, and the wafer 200 is supported on the lift pins 207 protruding from the surface of the substrate support 212. Thus, the wafer 200 is moved to the transfer position from the processing position. Then, the gate valve 205 is opened, and the wafer transferring mechanism is used to unload the wafer 200 to the outside of the processing container 202. At this time, the valve 245d is closed to stop supplying the inert gas into the processing container 202 through the third gas supply system 245.

When the wafer 200 is moved to the transfer position, the valve 262 is closed to block the transfer space 203 from the exhaust pipe 264 such that the transfer space 203 and the exhaust pipe 264 do not communicate with each other. Then, as the valves 266 and 267 are opened to exhaust the atmosphere of the transfer space 203 through the TMP 265 [and DP 282], the processing container 202 is maintained in a high vacuum (ultra-high vacuum) state, (for example, 10⁻⁵ Pa or less). Thus, a pressure difference between the processing container 202 and the transfer chamber which is maintained in a high vacuum (ultra-high vacuum) state, (for example, 10⁻⁶ Pa or less) is reduced. Meanwhile, an inert gas is supplied between the shaft 217 and the opening 208 through the inert gas supply pipe 221a, such that particles do not penetrate to the inner space of the bellows 219. Simultaneously, the inner atmosphere of the bellows 219 is exhausted through the bellows side exhaust pipe 222a. In this state, the gate valve 205 is opened to unload the wafer 200 to the transfer chamber from the processing container 202.

(Processing of Unprocessed Substrate)

The processes S102, S104 and S106 may be performed on unprocessed wafers 200 on standby.

The film forming technique is described above as a typical embodiment of the present invention. However, the present invention is not limited the embodiment. For example, the present invention may be also applied to cases in which other substrate processing processes are performed, the substrate processing processes including a process of forming another film as well as the above-described film, a diffusion process, an oxidation process, a nitridation process and a lithography process. The present invention may be applied to other substrate processing apparatuses such as annealing apparatus, a thin film foil ling apparatus, an etching apparatus, an oxidation apparatus, a nitridation apparatus, a coating apparatus and a heating apparatus. A portion of components of an arbitrary embodiment of the present invention may be replaced with components of another embodiment. Furthermore, components of another embodiment may be applied to components of an arbitrary embodiment. Other components may be added to a portion of the components of the present embodiments, or a portion of the components of the present embodiments may be removed or replaced.

In the above-described embodiment, TiCl₄ has been taken as an example of the first element containing gas, and Ti has been taken as an example of the first element. However, the present invention is not limited thereto. For example, the first element may include various elements such as Si, Zr and Hf. Furthermore, NH₃ has been taken as an example of the second element containing gas, and N has been taken as an example of the second element. However, the present invention is not limited thereto. For example, the second element may include O.

According to the embodiment of the present invention, the substrate processing apparatus can suppress the formation of particles.

What is claimed is:

1. A substrate processing apparatus comprising:
a processing container where a substrate is processed;
a process gas supply unit configured to supply a process gas into the processing container;
a substrate support installed in the processing container;
a first exhaust unit connected to the processing container;
a shaft supporting the substrate support;
a shaft support configured to support the shaft;
an opening disposed at a bottom portion of the processing container and penetrated by the shaft;
a flexible bellows disposed between the opening and the shaft support, wherein an inner space of the bellows is in communication with that of the processing container; and
a gas supply/exhaust unit configured to supply an inert gas into the inner space of the bellows while exhausting an inner atmosphere of the bellows.

2. The substrate processing apparatus of claim 1, further comprising:
an inert gas supply hole disposed between an upper end of the bellows and the bottom portion of the processing container; and
an bellows side exhaust hole disposed below the inert gas supply hole and configured to exhaust the inner atmosphere of the bellows,
wherein the gas supply/exhaust unit comprises: a first inert gas supply unit connected to the inert gas supply hole and configured to supply the inert gas into the inner space of the bellows; and a second exhaust unit in communication with the inner space of the bellows via the bellows side exhaust hole.

3. The substrate processing apparatus of claim 2, wherein the bellows side exhaust hole is disposed lower than a lower end of the bellows.

4. The substrate processing apparatus of claim 3, wherein the substrate support is at a transfer position when the substrate is transferred and at a processing position when the substrate is processed, and
the first inert gas supply unit is configured to supply the inert gas through the inert gas supply hole and the second exhaust unit is configured to exhaust the inner atmosphere of the bellows through the bellows side exhaust hole when the substrate support is at the transfer position.

5. The substrate processing apparatus of claim 3, further comprising a magnetic fluid seal disposed around an outer circumference of the shaft at a position lower than the bellows side exhaust hole.

6. The substrate processing apparatus of claim 3, wherein the process gas supply unit comprises: a source gas supply unit configured to supply a source gas; and a second inert gas supply unit configured to supply the inert gas, and
the gas supply/exhaust unit is configured to supply the inert gas into the inner space of the bellows when the source gas supply unit and the second inert gas supply unit supply the source gas and the inert gas into the processing container, respectively, where an amount of the inert gas supplied by the gas supply/exhaust unit when the source gas is supplied by the source gas supply unit is larger than that of the inert gas supplied by the gas supply/exhaust unit when the inert gas is supplied by the second inert gas supply unit.

7. The substrate processing apparatus of claim 3, wherein the process gas supply unit comprises: a reactive gas supply unit configured to supply a reactive gas; and a second inert gas supply unit configured to supply the inert gas, and
the gas supply/exhaust unit is configured to supply the inert gas into the inner space of the bellows when the reactive gas supply unit and the second inert gas supply unit supply the reactive gas and the inert gas into the processing container, respectively, where an amount of the inert gas supplied by the gas supply/exhaust unit when the reactive gas is supplied by the reactive gas supply unit is larger than that of the inert gas supplied by the gas supply/exhaust unit when the inert gas is supplied by the second inert gas supply unit.

8. The substrate processing apparatus of claim 2, wherein the substrate support is at a transfer position when the substrate is transferred and at a processing position when the substrate is processed, and
the first inert gas supply unit is configured to supply the inert gas through the inert gas supply hole and the second exhaust unit is configured to exhaust the inner atmosphere of the bellows through the bellows side exhaust hole when the substrate support is at the transfer position.

9. The substrate processing apparatus of claim 8, further comprising a magnetic fluid seal disposed around an outer circumference of the shaft at a position lower than the bellows side exhaust hole.

10. The substrate processing apparatus of claim 2, wherein the process gas supply unit comprises: a source gas supply unit configured to supply a source gas; and a second inert gas supply unit configured to supply the inert gas, and
the gas supply/exhaust unit is configured to supply the inert gas into the inner space of the bellows when the source gas supply unit and the second inert gas supply unit supply the source gas and the inert gas into the processing container, respectively, where an amount of the inert gas supplied by the gas supply/exhaust unit when the source gas is supplied by the source gas supply unit is larger than that of the inert gas supplied by the gas supply/exhaust unit when the inert gas is supplied by the second inert gas supply unit.

11. The substrate processing apparatus of claim 2, wherein the process gas supply unit comprises: a reactive gas supply unit configured to supply a reactive gas; and a second inert gas supply unit configured to supply the inert gas, and
the gas supply/exhaust unit is configured to supply the inert gas into the inner space of the bellows when the reactive gas supply unit and the second inert gas supply unit supply the reactive gas and the inert gas into the processing container, respectively, where an amount of the inert gas supplied by the gas supply/exhaust unit when the reactive gas is supplied by the reactive gas supply unit is larger than that of the inert gas supplied by the gas supply/exhaust unit when the inert gas is supplied by the second inert gas supply unit.

12. The substrate processing apparatus of claim 2, further comprising a controller configured to control at least the first inert gas supply unit and the second exhaust unit such that a conductance of a space between the shaft and an inner wall of the opening is larger than that of the bellows side exhaust hole.

13. The substrate processing apparatus of claim 12, further comprising a magnetic fluid seal disposed around an outer circumference of the shaft at a position lower than the bellows side exhaust hole.

14. The substrate processing apparatus of claim 2, further comprising a magnetic fluid seal disposed around an outer circumference of the shaft at a position lower than the bellows side exhaust hole.

15. The substrate processing apparatus of claim 1, wherein the process gas supply unit comprises: a source gas supply unit configured to supply a source gas; and a second inert gas supply unit configured to supply the inert gas, and
the gas supply/exhaust unit is configured to supply the inert gas into the inner space of the bellows when the source gas supply unit and the second inert gas supply unit supply the source gas and the inert gas into the processing container, respectively, where an amount of the inert gas supplied by the gas supply/exhaust unit when the source gas is supplied by the source gas supply unit is larger than that of the inert gas supplied by the gas supply/exhaust unit when the inert gas is supplied by the second inert gas supply unit.

16. The substrate processing apparatus of claim 1, wherein the process gas supply unit comprises: a reactive gas supply unit configured to supply a reactive gas; and a second inert gas supply unit configured to supply the inert gas, and
the gas supply/exhaust unit is configured to supply the inert gas into the inner space of the bellows when the reactive gas supply unit and the second inert gas supply unit supply the reactive gas and the inert gas into the processing container, respectively, where an amount of the inert gas supplied by the gas supply/exhaust unit when the reactive gas is supplied by the reactive gas supply unit is larger than that of the inert gas supplied by the gas supply/exhaust unit when the inert gas is supplied by the second inert gas supply unit.
